(19) United States
(12) Patent Application Publication
(10) Pub. No.: US 2026/0020387 A1
(43) Pub. Date: Jan. 15, 2026

(54) OPTOELECTRONIC SEMICONDUCTOR DEVICE COMPRISING AN EPITAXIALLY GROWN LAYER AND A METHOD OF MANUFACTURING THE OPTOELECTRONIC SEMICONDUCTOR DEVICE

(71) Applicant: ams-OSRAM International GmbH, Regensburg (DE)

(72) Inventors: Viola Miran Kueller, Barbing (DE); Hans-Jürgen Lugauer, Sinzing (DE); Marc Hoffmann, Regensburg (DE); Jürgen Off, Regensburg (DE)

(21) Appl. No.: 18/996,367

(22) PCT Filed: Aug. 8, 2023
(86) PCT No.: PCT/EP2023/071963

§ 371 Date: Jan. 17, 2025

(30) Foreign Application Priority Data
Aug. 10, 2022 (DE) 10 2022 120 161.9

(51) Int. Cl. H10H 20/831; H01S 5/042; H01S 5/183; H01S 5/30; H10H 20/01; H10H 20/814; H10H 20/82; H10H 20/825

(52) U.S. Cl. CPC H10H 20/8312; H01S 5/0421; H01S 5/18361; H01S 5/3013; H10H 20/0137; H10H 20/032; H10H 20/814; H10H 20/82; H10H 20/825

(57) ABSTRACT

In an embodiment a method for manufacturing an optoelectronic semiconductor device includes forming a semiconductor layer stack comprising a first semiconductor layer of a first conductivity type, a second semiconductor layer of a second conductivity type, and an active zone disposed between the first semiconductor layer and the second semiconductor layer, epitaxially growing a layer over a first main surface of the first semiconductor layer, wherein the epitaxially grown layer is based on growth parameters such that openings are formed in the epitaxially grown layer while epitaxially growing and forming a conductive layer over the epitaxially grown layer, wherein the conductive layer is electrically connected to the first semiconductor layer via the openings in the epitaxially grown layer.

### CROSS-REFERENCE TO RELATED APPLICATIONS

This patent application is a national phase filing under section 371 of PCT/EP2023/071963, filed Aug. 8, 2023, which claims the priority of German patent application no. 102022120161.9, filed Aug. 10, 2022, each of which is incorporated herein by reference in its entirety.

### TECHNICAL FIELD

Optoelectronic semiconductor devices, for example LEDs (light emitting diodes) or semiconductor lasers, usually comprise epitaxially grown semiconductor layers. Problems generally arise when further layers and a contact layer are applied over the semiconductor layer arrangement for generating electromagnetic radiation, and the contact layer is to be connected to the semiconductor layer stack through these further layers.

### SUMMARY

Embodiments provide an improved optoelectronic semiconductor device.

An optoelectronic semiconductor device includes a first semiconductor layer of a first conductivity type, a second semiconductor layer of a second conductivity type, and an active zone disposed between the first semiconductor layer and the second semiconductor layer. The optoelectronic semiconductor device further includes an epitaxially grown layer over a first main surface of the first semiconductor layer and a conductive layer over the epitaxially grown layer, wherein the conductive layer is electrically connected to the first semiconductor layer via openings in the epitaxially grown layer.

For example, the epitaxially grown layer includes a semiconductor or insulating layer. The epitaxially grown layer may comprise, for example, a layer sequence including undoped semiconductor layers or insulating layers. For example, the epitaxially grown layer may comprise a layer stack configured as a DBR mirror.

The optoelectronic semiconductor device may further include a conductivity enhancing layer in the first semiconductor layer adjacent to the first main surface.

The optoelectronic semiconductor device may further include a semiconductor contact layer having a plurality of portions protruding into the first semiconductor layer, wherein the semiconductor contact layer is arranged in the region of the first main surface of the first semiconductor layer.

For example, the first semiconductor layer may include GaN.

The optoelectronic semiconductor device may further include a contact material, which is different from a material of the conductive layer, in the openings in the epitaxially grown layer.

According to embodiments, a layer thickness of the epitaxially grown layer may be greater than or equal to 300 nm.

A method of manufacturing an optoelectronic semiconductor device comprises forming a semiconductor layer stack comprising a first semiconductor layer of a first conductivity type, a second semiconductor layer of a second conductivity type, and an active zone disposed between the first semiconductor layer and the second semiconductor layer. The method further includes epitaxially growing a layer over a first main surface of the first semiconductor layer and forming a conductive layer over the epitaxially grown layer, wherein the conductive layer is electrically connected to the first semiconductor layer via openings in the epitaxially grown layer.

For example, the method may include setting growth parameters in epitaxially growing the layer such that the openings are formed in the layer while epitaxially growing.

For example, the semiconductor layer stack may be formed by epitaxial methods.

The method may additionally include forming a contact material in the openings before forming the conductive layer, wherein the contact material is different from a material of the conductive layer.

### BRIEF DESCRIPTION OF THE DRAWINGS

The accompanying drawings serve to understand embodiments of the invention. The drawings illustrate embodiments and together with the description serve to explain them. Further embodiments and numerous of the intended advantages result directly from the following detailed description. The elements and structures shown in the drawings are not necessarily illustrated true to scale with respect to one another. Identical reference signs refer to identical or mutually corresponding elements and structures.

FIG. 1 shows a schematic cross-sectional view of an optoelectronic semiconductor device according to embodiments;

FIG. 2 shows a schematic cross-sectional view of an optoelectronic semiconductor device according to further embodiments;

FIG. 3 shows a schematic cross-sectional view of an optoelectronic semiconductor device according to further embodiments; and

FIGS. 4A to 4D illustrate a method of manufacturing an optoelectronic semiconductor device according to embodiments.

### DETAILED DESCRIPTION OF ILLUSTRATIVE EMBODIMENTS

In the following detailed description, reference is made to the accompanying drawings, which form a part of the disclosure and in which specific embodiments are shown for illustration purposes. In this context, directional terminology such as “top side”, “bottom”, “front side”, “rear side”, “over”, “on”, “in front”, “behind”, “front”, “rear”, etc. is referred to the orientation of the figures just described. Since the components of the embodiments can be positioned in different orientations, the directional terminology serves only for explanation and is in no way limiting.

The description of the embodiments is not limiting since other embodiments also exist and structural or logical changes can be made without deviating from the portion defined by the patent claims. In particular, elements of embodiments described below can be combined with elements of others of the described embodiments unless the context indicates otherwise.

The terms “wafer” or “semiconductor substrate” used in the following description can include any semiconductor-based structure having a semiconductor surface. Wafer and structure should be understood to include doped and undoped semiconductors, epitaxial semiconductor layers, if appropriate supported by a base support, and further semiconductor structures. For example, a layer of a first semiconductor material may be grown on a growth substrate of a second semiconductor material, for example a GaAs substrate, a GaN substrate or a Si substrate, or of an insulating material, for example on a sapphire substrate.

Depending on the intended use, the semiconductor may be based on a direct or an indirect semiconductor material. Examples of semiconductor materials particularly suitable for generating electromagnetic radiation include, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, and further semiconductor materials such as GaAs, AlGaAs, InGaAs, AlInGaAs, SiC, ZnSe, ZnO, Ga₂O₃, diamond, hexagonal BN and combinations of the materials mentioned. The stoichiometric ratio of the compound semiconductor materials may vary. Further examples of semiconductor materials may include silicon, silicon-germanium and germanium.

The term “substrate” generally includes insulating, conductive or semiconductor substrates.

The term “vertical” as used in this description is intended to describe an orientation which is substantially perpendicular to the first surface of a substrate or semiconductor body. The vertical direction may correspond, for example, to a growth direction when growing layers.

The terms “lateral” and “horizontal” as used in this description are intended to describe an orientation or orientation which is substantially parallel to a first surface of a substrate or semiconductor body. This may be, for example, the surface of a wafer or a chip (die).

The horizontal direction may lie, for example, in a plane perpendicular to a growth direction when growing layers.

In the context of this description, the term “electrically connected” means a low-ohmic electrical connection between the connected elements. The electrically connected elements do not necessarily have to be directly connected to one another. Further elements may be arranged between electrically connected elements.

The term “electrically connected” also includes tunnel contacts between the connected elements.

In the following description, reference is made to a first semiconductor layer of a first conductivity type and to a second semiconductor layer of a second conductivity type. The first semiconductor layer and/or the second semiconductor layer may each comprise a plurality of different layers. For example, the first semiconductor layer may include a plurality of semiconductor layers each of a first conductivity type. For example, the individual semiconductor layers may differ in their composition ratio.

The first semiconductor layer may further comprise a semiconductor contact layer in the region of the first main surface. The semiconductor contact layer may, for example, be heavily doped with the charge carriers of the first conductivity type. For example, current may be impressed into the first semiconductor layer predominantly via the contact layer. The contact layer may, for example, be necessary when an electrical barrier between the conductive layer and the first semiconductor layer is comparatively high for physical reasons.

In a corresponding manner, the second semiconductor layer may comprise a plurality of layers of a second conductivity type. At least one of the first and second semiconductor layers may further include a partial layer, which is not necessarily doped, as a barrier layer for minority charge carriers. The layer thickness of such a barrier layer is at most 15 nm or at most 10 nm.

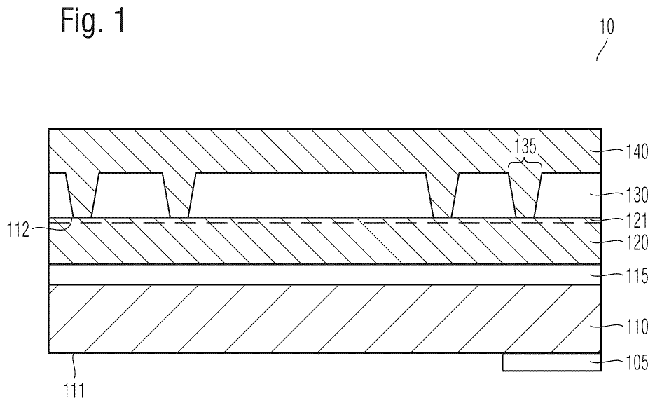

FIG. 1 shows a cross-sectional view of an optoelectronic semiconductor device 10 according to embodiments. The optoelectronic semiconductor device 10 includes a first semiconductor layer 120 of a first conductivity type, a second semiconductor layer 110 of a second conductivity type, and an active zone 115 disposed between the first semiconductor layer 120 and the second semiconductor layer 110. For example, the first and second semiconductor layers may include GaN, InGaN or AlGaN. For example, the first semiconductor layer may be of the p-conductivity type. Furthermore, the second semiconductor layer may be of the n-conductivity type.

The active zone 115 may comprise, for example, a pn-junction, a double heterostructure, a single quantum well (SQW) structure or a multi quantum well (MQW) structure for generating radiation. The term “quantum well structure” here does not have any significance with regard to the dimensionality of the quantization. It thus includes, inter alia, quantum wells, quantum wires and quantum dots and any combination of these layers.

An epitaxially grown layer 130 may be arranged over a first main surface 112 of the first semiconductor layer 120. The epitaxially grown layer 130 may in turn comprise a plurality of different layers. For example, the epitaxially grown layer 130 may be non-conductive, i.e., non-metallic. For example, the epitaxially grown layers may be predominantly undoped. According to further embodiments, they may also be configured as insulating layers. The epitaxially grown layer(s) may, for example, have a lower conductivity than the first semiconductor layer.

For example, the epitaxially grown layer may represent a mirror layer or DBR (“distributed Bragg reflector”) layer.

Generally, the term “DBR layer” includes any arrangement which reflects incident electromagnetic radiation to a large degree (for example >90%) and is non-metallic. For example, a DBR layer may be formed by a sequence of very thin, for example undoped semiconductor layers each having different refractive indices. For example, the layers may alternately have a relatively high refractive index (n>n₁) and a low refractive index (n≤n₁) and be configured as a Bragg reflector. The refractive index n₁ may be selected in accordance with the material system used. For example, the layer thickness may be λ/4, wherein λ indicates the wavelength of the light to be reflected in the respective medium. The layer viewed from the incident light may have a greater layer thickness, for example 3λ/4. On account of the low layer thickness and the difference in the respective refractive indices, the DBR layer provides a high reflectivity and at the same time is non-conductive. The DBR layer is thus configured to insulate components of the semiconductor device from one another. A DBR layer may comprise, for example, 2 to 50 individual layers. A typical layer thickness of the individual layers may be approximately 30 to 90 nm, for example approximately 50 nm. The layer stack may further include one or two or more layers which are thicker than approximately 180 nm, for example thicker than 200 nm.

For example, the epitaxially grown layer 130 may comprise a plurality of thin AlₓGa₁₋ₓN/Al_{y}Ga_{1-y}N layers where x≠y. For example, the Ga content of the respective layers may be highly different from one another. For example, the absolute value of the difference between x and y may be greater than 0.3 or greater than 0.4. For example, x≥0.7 and y≤0.3 or vice versa. According to further examples, x≥0.75 and y≤0.25 or vice versa. According to further embodiments, the epitaxially grown layer 130 may comprise a plurality of thin InₓGa₁₋ₓN/In_{y}Ga_{1-y}N layers where x≠y.

For example, a layer thickness of the epitaxially grown layer 130 may be 300 nm or greater, for example 500 nm or greater.

A conductive layer is arranged over the epitaxially grown layer 130. The conductive layer 140 is electrically connected to the first semiconductor layer 120 via openings 135 in the epitaxially grown layer 130. The epitaxially grown layer 130 does not form a closed surface, for example.

As further illustrated in FIG. 1, the optoelectronic semiconductor device 10 may comprise a contact element 105, which is arranged over a first main surface 111 of the second semiconductor layer 110, for example. A current may be impressed into the optoelectronic semiconductor device 10 via the contact element 105 and the electrically conductive layer 140, for example. In the portion of the active zone, charge carriers may recombine under emission of electromagnetic radiation. The optoelectronic semiconductor device may be configured as an LED, for example. According to further embodiments, the optoelectronic semiconductor device 10 may also be configured as a laser. For example, the laser may be configured as a VCSEL (vertical-cavity surface-emitting laser). In this case, a further mirror may be arranged on the side of the first main surface 111 of the second semiconductor layer 110, for example, such that an optical resonator extends in the vertical direction.

For example, the openings 135 may be generated by influencing the growth processes when epitaxially growing the layer 130. The epitaxial growth may take place as so-called island growth. For example, growth parameters, for example pressure and temperature, may be set in a suitable manner. For example, the growth may take place at higher temperatures than usual. According to embodiments, the growth parameters may be set such that paths remain between adjacent islands (uncoalesced surfaces) in the course of the growth process. These paths then act as openings 135 via which the first semiconductor layer may be contacted.

According to further embodiments, openings 135 may also be formed by so-called inversion domains in which the polarity of the growth is locally reversed. In turn, a nitrogen polarity may be generated instead of a metal polarity by setting the growth parameters in the epitaxial method, for example in the case of growth of GaN or AIN layers. This may be achieved, for example, by an unfavorable nitrogen/NH₃ ratio of the gases used in the epitaxial method. In this manner, openings may be generated in the epitaxially grown layer.

For example, charge carriers may be distributed via a conductivity enhancing layer 121, which represents part of the first semiconductor layer and is arranged adjacent to the first main surface 112. The conductivity enhancing layer 121 may be realized, for example, as a tunnel layer or a so-called 2DHG (“two-dimensional hole gas”) layer. In the case of such a layer, the composition ratio and/or the doping is changed with respect to the first semiconductor layer 120, so that it acts as a tunnel layer or as a 2DHG layer.

For example, the LED described may be used for disinfection or for illumination.

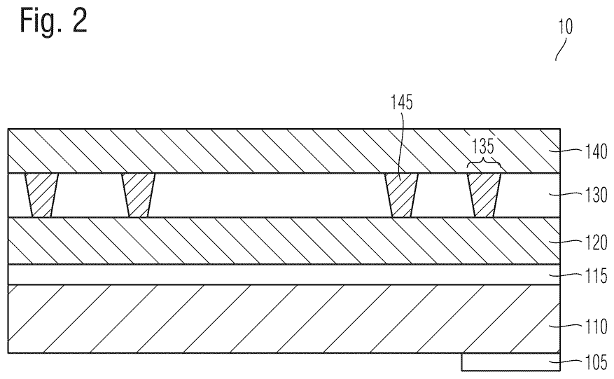

FIG. 2 shows a schematic cross-sectional view of an optoelectronic semiconductor device 10 according to further embodiments. The optoelectronic semiconductor device 10 may comprise similar or identical components to that shown in FIG. 1. In addition, a contact material 145, which is introduced in the openings 135, may differ from the conductive material 140. For example, the contact material 145 may be selected in order to realize the lowest possible ohmic resistance between the first semiconductor layer 120 or a semiconductor contact layer. Examples of a particularly suitable contact material include, inter alia, Pt, Ni, Au, ITO (indium tin oxide). The material of the conductive layer 140 may be selected in order to provide a high reflectivity. For example, a material of the conductive layer 140 may include aluminum, ITO or rhodium.

In this manner, an optoelectronic component having improved properties may be provided.

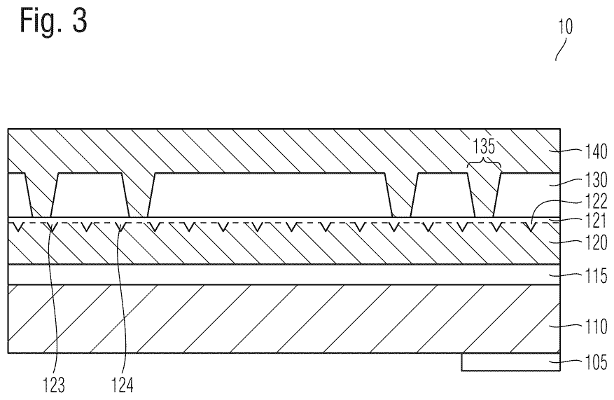

FIG. 3 shows a schematic cross-sectional view of an optoelectronic semiconductor device according to further embodiments. The optoelectronic semiconductor device 10 of FIG. 3 comprises similar or identical components to the respective semiconductor devices of FIGS. 1 and 2. In addition, a first semiconductor contact layer 122 having a varying layer thickness is illustrated.

For example, the first semiconductor contact layer 122 may comprise a plurality of portions 124 protruding into the first semiconductor layer 120. The protruding portions 124 may comprise, for example, a different composition ratio than the first semiconductor layer 120 or a different doping level. If the first semiconductor layer 120 includes further semiconductor layers of the first conductivity type, the wording “different composition” or “different dopant concentration” always relates to the layer(s) directly adjacent to the protruding portion 124.

According to embodiments, the first semiconductor contact layer 122 may consist exclusively of such protruding portions 124. According to further embodiments, as illustrated in FIG. 3, a thin first semiconductor contact layer 122 may additionally be configured as a filling layer such that the individually protruding portions 124 are connected to one another.

For example, the protruding portions may be formed by forming V-shaped defects or pits in the first semiconductor layer 120, as described in document WO 2018/167011 A1. In this manner, an improved electrical contact to the conductive layer 140 may be achieved without radiation losses due to absorption in the first semiconductor contact layer 122 becoming too great.

As has been described, it is possible by a specific implementation of the epitaxial layer to grow an epitaxial layer over the second semiconductor layer and to electrically connect a conductive layer disposed thereover to the first semiconductor layer 120.

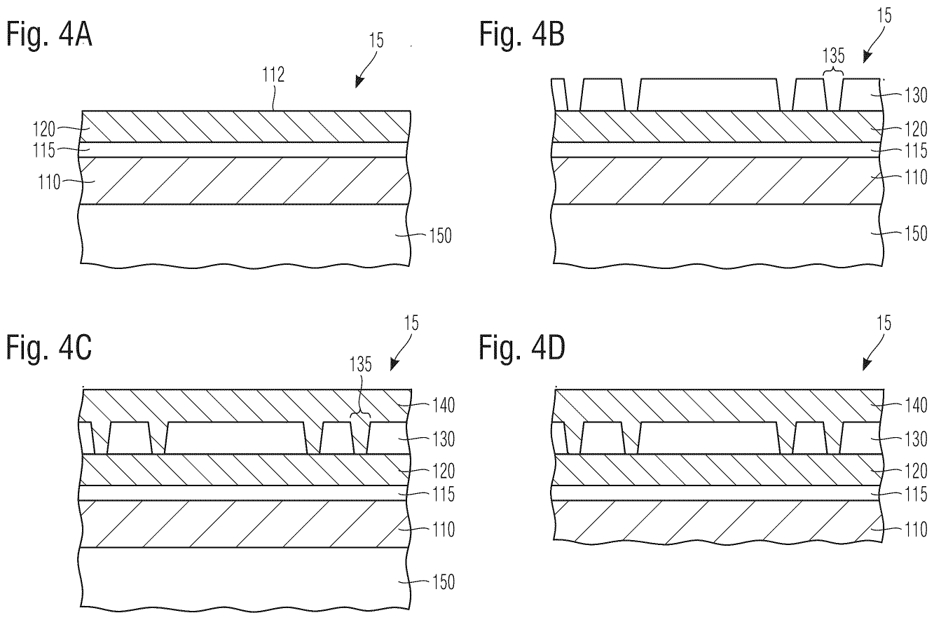

FIGS. 4A to 4D illustrate an example of a method of manufacturing the optoelectronic semiconductor device described above.

A second semiconductor layer 110 of a second conductivity type, layers for forming the active zone 115, and a first semiconductor layer 120 of a first conductivity type are grown over a suitable growth substrate 150, which may include, for example, sapphire or aluminum nitride. FIG. 4A shows an example of a resulting workpiece 15. For example, the layer 110 may be n-doped and the second semiconductor layer 120 is p-doped.

An epitaxial layer 130 is then applied over the first main surface 112 of the first semiconductor layer 120. The epitaxial layer 130 may comprise a plurality of individual layers. For example, a plurality of openings 135 are formed in the epitaxial layer 130 by a corresponding setting of the growth conditions, as discussed with reference to FIG. 1. FIG. 4B shows an example of a resulting workpiece 15. The openings 135 may, for example, each have a size of approximately 10 nm² to 5 μm², for example approximately 0.5 μm² to 1.5 μm², and a density of approximately 10⁵ openings/cm² to 10¹⁰ openings/cm², for example approximately 10⁶ openings/cm².

Subsequently, as illustrated in FIG. 4C, a conductive layer 140 is applied over the surface. As a result, the openings 135 are filled with the material of the conductive layer 140. Alternatively, this method may also be carried out in two stages, wherein first a contact material, as illustrated in FIG. 2, and then the conductive layer 130 is applied.

In the case of the described dimensioning and density of the openings, the contact area is approximately 1:100. Accordingly, the properties, for example the reflection property, of the epitaxially grown layer 130 are not greatly influenced by the openings 135.

FIG. 4D shows an example of the workpiece 15 after removal of the growth substrate 150.

Although specific embodiments have been illustrated and described herein, those skilled in the art will recognize that the specific embodiments shown and described may be replaced by a multiplicity of alternative and/or equivalent embodiments without departing from the scope of protection of the invention. The application is intended to cover any adaptations or variations of the specific embodiments discussed herein. Therefore, the invention is limited only by the claims and the equivalents thereof.

1.-11. (canceled)

12. A method for manufacturing an optoelectronic semiconductor device, the method comprising:
forming a semiconductor layer stack comprising a first semiconductor layer of a first conductivity type, a second semiconductor layer of a second conductivity type, and an active zone disposed between the first semiconductor layer and the second semiconductor layer;
epitaxially growing a layer over a first main surface of the first semiconductor layer, wherein the epitaxially grown layer is based on growth parameters such that openings are formed in the epitaxially grown layer while epitaxially growing; and
forming a conductive layer over the epitaxially grown layer, wherein the conductive layer is electrically connected to the first semiconductor layer via the openings in the epitaxially grown layer.

13. The method of claim 12, wherein the semiconductor layer stack is formed by epitaxial methods.

14. The method of claim 12, further comprising forming a contact material in the openings before forming the conductive layer, wherein the contact material is different from a material of the conductive layer.

15. An optoelectronic semiconductor device comprising:
a first semiconductor layer of a first conductivity type;
a second semiconductor layer of a second conductivity type;
an active zone disposed between the first semiconductor layer and the second semiconductor layer;
an epitaxially grown layer located over a first main surface of the first semiconductor layer, wherein the epitaxially grown layer does not form a closed surface and openings are formed in the epitaxially grown layer; and
a conductive layer located over the epitaxially grown layer, wherein the conductive layer is electrically connected to the first semiconductor layer via the openings in the epitaxially grown layer; and
a conductivity enhancing layer located in the first semiconductor layer adjacent to the first main surface.

16. The optoelectronic semiconductor device of claim 15, wherein the epitaxially grown layer includes a semiconductor or insulating layer.

17. The optoelectronic semiconductor device of claim 16, wherein the epitaxially grown layer comprises a layer stack configured as a DBR mirror.

18. The optoelectronic semiconductor device of claim 15, wherein the first semiconductor layer includes GaN.

19. The optoelectronic semiconductor device of claim 15, further comprising a contact material, which is different from a material of the conductive layer, in the openings of the epitaxially grown layer.

20. The optoelectronic semiconductor device of claim 15, wherein a layer thickness of the epitaxially grown layer is greater than or equal to 300 nm.

21. The optoelectronic semiconductor device according to claim 15, wherein the conductivity enhancing layer forms a two-dimensional hole gas layer.
